(19) United States
(12) Patent Application Publication
(10) Pub. No.: US 2006/0225649 A1
(43) Pub. Date: Oct. 12, 2006

(54) Deposition reactor and method of determining its diffuser

(75) Inventor: Jerome Courville, Grenoble (FR)

Correspondence Address: JENKENS & GILCHRIST, PC, 1445 ROSS AVENUE, SUITE 3200, DALLAS, TX, 75202, US

(73) Assignee: STMicroelectronics S.A., Montrouge (FR)

(21) Appl. No.: 11/391,001

(22) Filed: Mar. 28, 2006

(30) Foreign Application Priority Data
Apr. 1, 2005 (FR) 0503200

(51) Int. Cl. C23C 16/52; C23C 16/00

(52) U.S. Cl. 118/715; 427/8; 427/248.1

(57) ABSTRACT

A deposition reactor for use in depositing a film of oxide having a high permittivity or dielectric constant on a wafer. The reactor includes a diffuser whose front face is formed so that the gap between a peripheral part and an upper face of the wafer to be treated decreases from its periphery towards its center. The reactor is equipped with dilution gas flow controller and with at least two independent local heating/cooling devices supporting independent control and/or regulation of thermal power.

### PRIORITY CLAIM

The present application claims priority from French Application for Patent No. 05 03200 filed Apr. 1, 2005, the disclosure of which is hereby incorporated by reference.

### BACKGROUND OF THE INVENTION

1. Technical Field of the Invention

The present invention relates to the field of deposition reactors and more particularly to reactors for depositing an oxide having a high dielectric constant or permittivity, such as a ceramic oxide, in particular tantalum pentoxide (Ta₂O₅), such reactors being used in the field of the fabrication of integrated circuits on wafers.

2. Description of Related Art

At the present time, there is a need to be able to fabricate capacitors whose dielectric film has a high dielectric constant and a thickness which is as uniform as possible from one capacitor to another, and to do so on all the capacitors of the integrated circuits produced on the same wafer.

Such capacitors are indeed desired in particular in integrated radiofrequency (RF) decoupling circuits, in integrated circuits generally called DRAMs in which an ever higher density of capacitors is desired, and in analog integrated circuits such as converters, in which capacitance values as precise as possible are desired.

Unfortunately, the deposition reactors that are known and used at the present time are incapable of achieving the above objectives. This is because the dielectric films that are deposited have circumferential regions which, in radial section, have domed parts and depressed parts and which also have unequal thicknesses going from one radius to the opposite radius.

There is a need in the art for an improvement to deposition reactors for the purpose of reducing the non-uniformity of the film deposited on a wafer.

### SUMMARY OF THE INVENTION

The present invention relates more particularly to a deposition reactor which comprises an enclosure defining a treatment chamber, a support on which a wafer having an upper face to be treated can be placed in said treatment chamber, a plate-shaped diffuser, which has through-holes between a front face placed above and at some distance from the upper face of the wafer to be treated and a rear face opposite this front face and which divides said treatment chamber into a distribution chamber located on the same side as the rear face of the diffuser and a reaction chamber located on the same side as the front face of the diffuser, and an annular passage formed in the reaction chamber around said support.

Said enclosure is provided with reaction gas intake means opening into said distribution chamber, peripheral gas exhaust means opening into said reaction chamber on the same side as the wafer relative to said annular passage, and dilution gas intake means opening into said reaction chamber and placed so that this gas flows through said annular passage before being exhausted via said gas exhaust means.

According to the invention, the peripheral part of said front face of the diffuser is preferably formed so that the gap between this peripheral part and the upper face of said wafer to be treated decreases from its periphery towards its center.

According to one version of the invention, said peripheral part of the front face of the diffuser may be conical.

According to the invention, the cone angle of said conical peripheral part of the front face of the diffuser preferably ranges from 160° to 175°.

According to another version of the invention, said peripheral part of the front face of the diffuser may be rounded.

According to the invention, the central part of the front face of the diffuser may be set back or hollowed.

According to the invention, said central part of the front face of the diffuser may have a conical annular part open on the same side as said wafer.

According to the invention, the cone angle of said conical central part of the front face of the diffuser may range from 175° to 179.5° approximately.

The subject of the present invention is also a method of determining the shape of the front face of a plate-shaped gas diffuser of a deposition reactor, said front face being placed facing the surface of a circular wafer to be treated, in which the operating conditions of the reactor are predetermined.

According to the invention, this method comprises: in installing in the reactor a first, trial diffuser, the front face of which has a defined profile, preferably a flat front face; in carrying out a deposition operation on a surface of a trial wafer; in recording the topography of the treated surface of the trial wafer; in producing a second diffuser having a front face whose topography has at least one annular part substantially the reverse of that of the treated surface of the trial wafer; and in installing this second diffuser in the reactor for the purpose of treating standard wafers.

According to the invention, the method may advantageously comprise in producing a second diffuser whose front face has at least one conical or rounded annular part whose cone angle is substantially the reverse of and in a defined ratio with respect to the mean cone angle of the corresponding annular part of the trial wafer.

According to the method of the invention, said conical or rounded annular part is located on the periphery of the front face of said second diffuser.

According to another subject of the invention, the reactor may advantageously include flow control means for said dilution gas intake means.

According to another subject of the invention, the reactor may advantageously include at least two independent local heating/cooling means that are carried by the wall of the enclosure adjacent to said distribution chamber and located in the peripheral region of this chamber, and also independent means for controlling and/or regulating the thermal power provided by these heating/cooling means.

According to the invention, said local heating/cooling means are preferably attached to the outer face of said wall of the enclosure.

According to the invention, said local heating/cooling means preferably comprise electrical resistors.

According to the invention, said resistors are preferably placed in a groove made in the outer face of said wall of the enclosure.

According to the invention, said independent control and/or regulation means preferably comprise thermal sensors carried by said wall of the enclosure and located in the vicinity of said independent local heating/cooling means, control means for setting temperature setpoint values, and regulating means for regulating said heating means so that said thermal sensors deliver measurements corresponding to said setpoint values.

In an embodiment of the invention, a deposition reactor comprises an enclosure defining a treatment chamber for a wafer having an upper face to be treated, and a plate-shaped diffuser having through-holes between a front face placed above and at some distance from the upper face of the wafer to be treated and a rear face opposite this front face. A peripheral part of said front face of the diffuser is formed so that a gap between the front face of the diffuser at this peripheral part and the upper face of said wafer to be treated decreases from the periphery of the diffuser towards its center.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 shows, in a plane of section containing its axis, a deposition reactor according to the present invention;

FIG. 2 shows an enlarged sectional view of the upper part of said reactor;

FIG. 3 shows an enlarged sectional view of the upper part of said reactor, equipped with a diffuser according to the invention;

FIG. 4 shows an enlarged sectional view of the upper part of said reactor, corresponding to FIG. 3;

FIG. 5 shows a sectional view of another diffuser according to the invention;

FIG. 6 shows a sectional view of another diffuser according to the invention;

FIG. 7 shows, in a plane of section containing its axis, a deposition reactor according to the present invention, equipped with heating means;

FIG. 8 shows a top view of the reactor of FIG. 7; and

FIG. 9 shows an electrical circuit diagram associated with the reactor of FIG. 7.

### DETAILED DESCRIPTION OF THE PREFERRED EMBODIMENTS

The deposition reactor 1 that will now be described is more especially suitable for the deposition of an oxide having a high dielectric constant or permittivity, such as a ceramic oxide, in particular tantalum pentoxide (Ta₂O₅).

This reactor 1 comprises a hollow enclosure 2, which is generally of parallelepipedal form.

This enclosure 2 comprises a lower body 3, generally in the form of a cylindrical dish, and a generally flat lid 4, which together define a treatment chamber 5.

The deposition reactor 1 includes a diffuser 6 which comprises a horizontal disk 7 and a peripheral ring 8 projecting axially upwards, which ring is engaged in the periphery of a central circular recess 9 made in the lower face of the lid 4, in such a way that this diffuser divides the treatment chamber 5 into a quite flat distribution chamber 10, which extends between the rear face of the diffuser and the lid, in the recess 9, and into a reaction chamber 11 on the same side as the lower front face 12 of the diffuser.

The diffuser 6 has a multiplicity of vertical through-holes 13.

The deposition reactor 1 includes a support 14 which has a tray 15 that is placed in the reaction chamber 11 and has an upper face 16 on which a circular wafer 17 to be treated may be installed, at a certain distance below the front face 12 of the diffuser 6. The support 14 further includes a vertical central pillar 18 that carries the tray 15 and passes through the lower wall of the body 3 and the enclosure 2, this pillar being connected to means (not shown) for adjusting the gap between the front face 12 of the diffuser 6 and the upper face of the wafer 17 to be treated.

The tray 15 is provided with means (not shown) for heating the wafer 17 as uniformly as possible.

At some distance from the periphery of the tray 15, the body 3 has an annular step 19 in which an annular gutter 20 is hollowed out. Fixed to this step is a horizontal ring 21 having a multiplicity of passages 22 for communication between the reaction chamber 11 and the gutter 20, so as to form an annular gas manifold 23.

The body 3 has channels 24 connected to means (not shown) for making a coolant circulate therein.

The deposition reactor 1 further includes a reaction gas feed pipe 25 comprising a vertical portion 26 made in one corner of the body 3, an outer upstream portion 27 connected to the lower end of the portion 26 and provided with a flow control valve 27a, and an outer downstream portion 28 in the form of an inverted U shape, one end of which is connected to the upper end of the portion 26 and its other end is connected to a through-passage 29 made at the center of the lid 4.

The pipe 25 is connected, upstream of the valve 27a, to means (not shown) for delivering a reaction gas.

The pipe 25 is equipped with means (not shown) for heating the reaction gas.

The deposition reactor 1 further includes a dilution gas feed pipe 30 which communicates with the reaction chamber via a passage made in the lower wall of the body 3, around the pillar 18.

The deposition reactor 1 further includes an external gas exhaust pipe 32, which is connected to the gas manifold 23 through a passage 33 made in the side wall of the body 3 and is equipped with a pump 34.

The deposition reactor 1 generally operates in the following manner.

According to one example, the wafer may have a diameter of about 200 mm and the gap between the front face 12 of the diffuser 6 and the face of the wafer 17 to be treated may be between 10 and 17 mm, especially about 15 mm.

The wafer is heated via the tray 15.

A hot reaction gas coming from the feed pipe 25 is introduced into the distribution chamber 10, flows through holes 8 in the diffuser 6, flows into the space 11 a lying between the front face 12 of the diffuser 6 and the upper face of the wafer 17 to be treated and exits approximately radially to the periphery of this space. While said gas is flowing through the space 11a, a film is deposited on the upper face of the wafer 17.

A hot dilution gas coming from the feed pipe 30 is introduced into the reaction chamber 11 beneath the tray 15 and flows through the annular passage 11b formed between the periphery of the tray 15 and the inner edge of the ring 21.

The reaction gas and the dilution gas are therefore directed approximately radially towards the manifold 23 and are sucked out into the exhaust pipe 32.

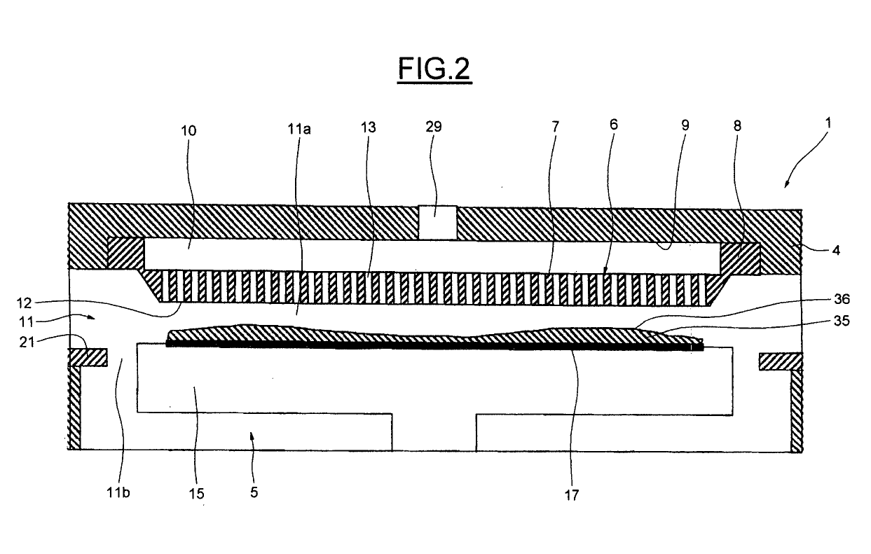

By applying operating conditions for depositing a film of defined thickness on the wafer 17, that is to say in particular applying defined values of the temperature of the tray 15, the temperature and flow rate of the gases and a defined gap between the front face 12 of the diffuser 6 and the wafer 17, and by using a diffuser 6 whose front face 12 is flat, what is generally obtained is, for example, a film 35 whose profile 36 is shown in cross section in FIG. 2.

As FIG. 2 shows, the profile 36 is not uniform—it comprises a domed projecting mid-annular region formed between a hollow central region and a downward peripheral region—this non-uniformity possibly being between 7% and 10%.

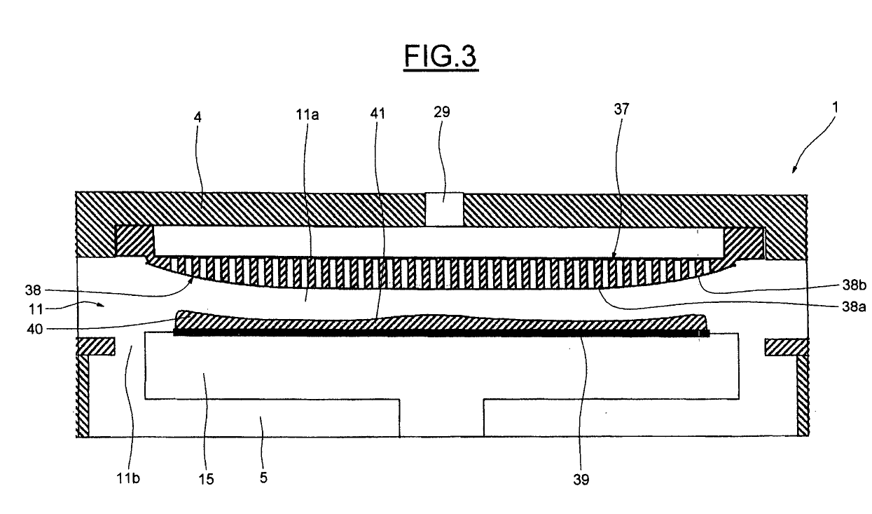

This profile is not satisfactory, and therefore the aim is to produce a diffuser 37 whose front face 38 is not flat, such as the one shown for example in FIG. 3 and installed in the deposition reactor 1 instead of the diffuser 6.

The front face 38 of this diffuser 37 has a flat central part 38a and a peripheral part 38b rounded in such a way that the distance between this rounded part 38b and the face of a wafer 17a to be treated decreases from its periphery towards its center, that is to say until joining the central part 38a tangentially. Preferably, the rounded part 38b is, in cross section, in the form of a parabola.

A deposition operation is then carried out on a wafer 39, applying said operating conditions.

As shown in FIG. 3, what is then obtained is a deposited film 40 whose profile 41 is less non-uniform.

According to this example, the profile 41 of the film 40 deposited on the wafer 39 has a slightly rising peripheral part.

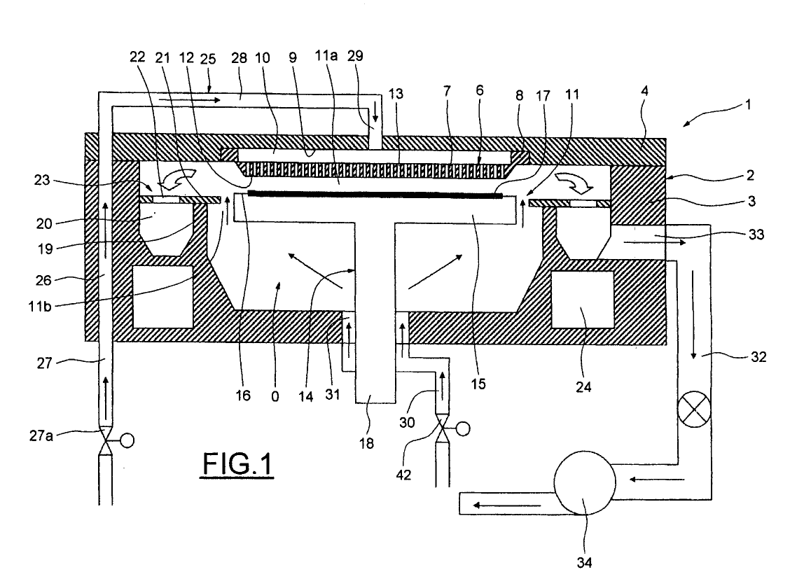

As shown in FIG. 1, the deposition reactor 1 is further equipped with a valve 42 mounted on the dilution gas feed pipe 30.

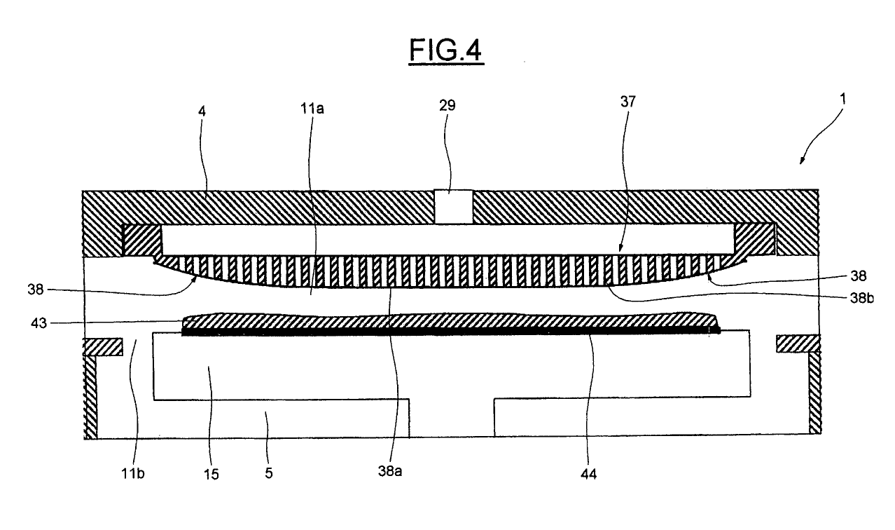

As shown in FIG. 4, it is possible, by adjusting this valve 42 so as to increase the flow rate of the dilution gas, to deposit on a wafer 44, under said operating conditions, a film 43 in which the aforementioned slightly rising profile of its peripheral part is reduced.

In fact, the dilution gas flows advantageously around the periphery of the upper edge of the tray 15 and therefore joins up with the reaction gas near the periphery of the wafer to be treated. These gases are directed radially outwards towards the manifold 23. By adjusting the flow rate of the dilution gas, by acting on the control member of the valve 42, a thickness of the peripheral part of the film deposited on a wafer matched to the thickness of this film deposited elsewhere on this wafer may advantageously be obtained.

Moreover, the front face of the diffuser used may advantageously take forms other than that proposed above.

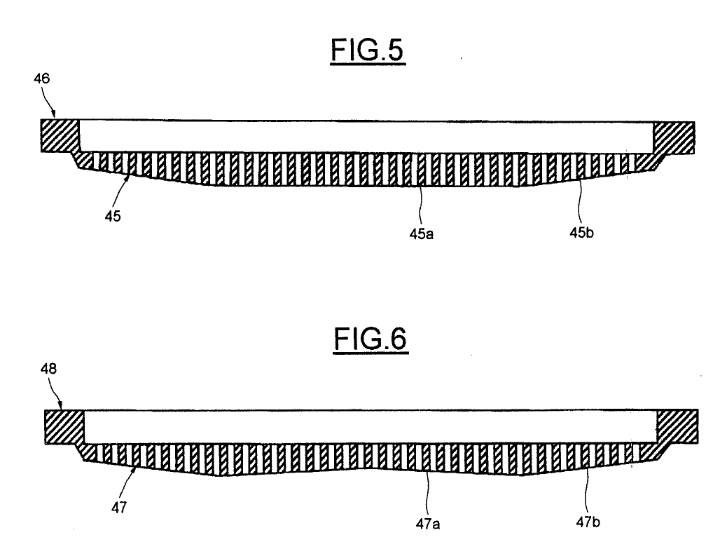

As shown in FIG. 5, the possible front face 45 of another diffuser 46 that can be used may advantageously have a flat central part 45a and a conical peripheral part 45b, the cone angle of which could range from 160° to 175°.

As shown in FIG. 6, the possible front face 47 of another diffuser 48 that can be used may advantageously have a concave conical central part 47a, the cone angle of which could range from 175° to 179.5°, and a conical peripheral part 47b whose cone angle could range from 160° to 175°.

To determine the profile of the front face of a suitable diffuser, the following procedure could be carried out.

Firstly, a trial diffuser 6 whose front face 12 is flat is installed in the deposition reactor 1.

A deposition operation is carried out on a surface of a trial wafer 17, under operating conditions defined according to the desired thickness of the film deposited.

Next, the trial wafer is extracted and the topography of the treated surface of this trial wafer 17 is recorded.

A second diffuser having a front face whose topography has at least one annular part substantially the reverse of that of the treated surface of the trial wafer is produced, for example one corresponding to the diffuser 37 or the diffuser 45. It would also be possible to produce a diffuser corresponding to the diffuser 48, taking into account the profile of the central part of the trial wafer. In one embodiment, the cone angle of the diffuser is substantially the reverse of and in a defined ratio with respect to a mean cone angle of the corresponding annular part of the trial wafer.

Finally, this second diffuser is installed in the deposition reactor 1 for the purpose of treating standard wafers.

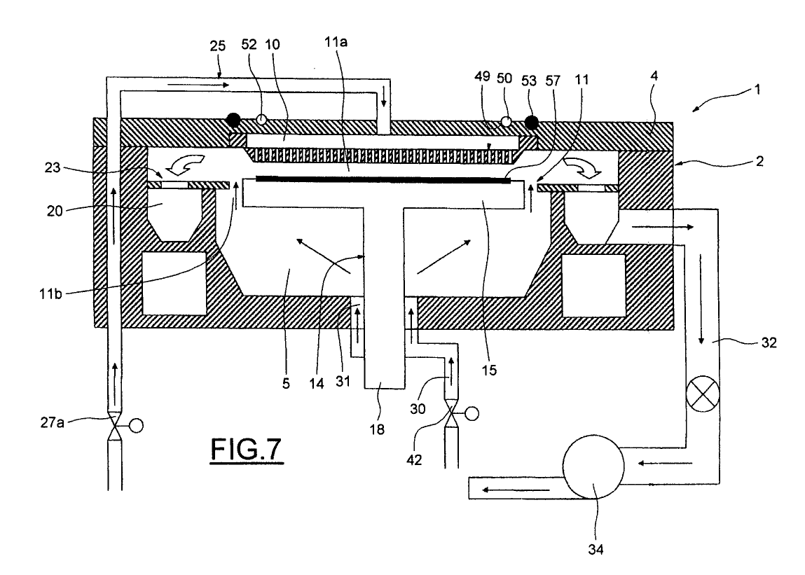

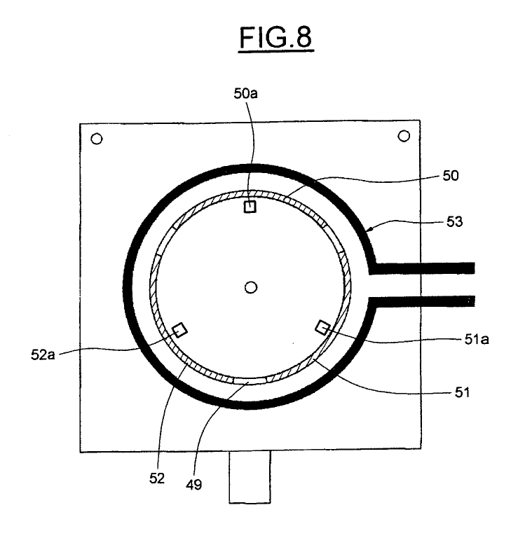

Referring to FIGS. 7 and 8, it may be seen that the upper face of the lid 4 of the deposition reactor 1 may have an annular groove 49 made in its region corresponding to the peripheral part of the distribution chamber 10.

Attached in this groove 49 are, in the example, three independent bowed electrical resistors 50, 51 and 52 distributed more or less evenly.

Fitted on the upper face of the lid 4 are for example three independent thermal sensors 50a, 51a and 52a, placed near the resistors 50, 51 and 52, on the inside, and more or less distributed evenly.

Also fitted on the upper face of the lid 4 is an annular coolant circulation pipe 53 placed around and at a certain distance from the groove 49. This annular pipe 53 is connected to an external supply of coolant.

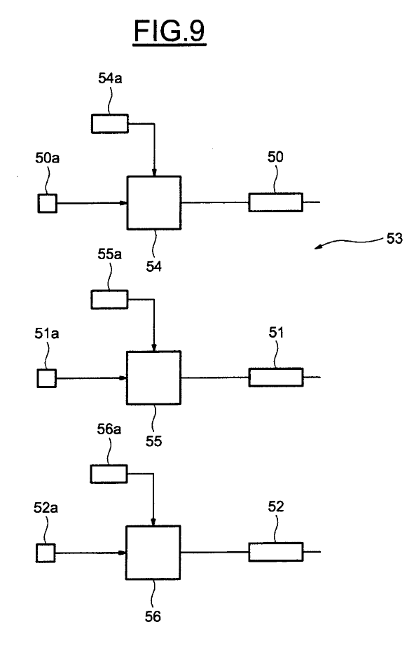

FIG. 9 shows an electronic circuit diagram 53 for supplying the resistors 50, 51 and 52 independently.

The sensors 50a, 51a and 52a are connected, respectively, to circuits 54, 55 and 56 for regulating the electrical supply for the resistors 50, 51 and 52, which are provided with control knobs 54a, 55a and 56a for setting setpoint values. Conventionally, each regulation circuit supplies each resistor so that the corresponding sensor delivers a measured value corresponding to the desired corresponding setpoint value.

The purpose of adding the resistors 50, 51 and 52 is to heat, to a greater or lesser extent, independently, the reaction gas flowing through the corresponding regions of the distribution chamber 10, especially via the heat that they supply to the lid 4, so as to more or less compensate for any circumferential thermal imbalance of the mass formed by the walls of the enclosure 3, which imbalance has a tendency to induce a circumferential non-uniformity in the film deposited on a treated wafer.

To do this, wafers 57 are placed in succession on the tray 15, on which deposition operations are carried out, applying said operating conditions, each time modifying the setting of the setpoint control knobs 54a, 55a and 56a until a deposited film thickness having an acceptable circumferential non-uniformity is obtained.

By applying the provisions described, relating to the front face of the diffuser and/or to the control of the dilution gas flow rate and/or to the local thermal regulation of the lid temperature, it is possible to reduce the non-uniformity of the film deposited on wafers down to a value that may be between 1.5% and 3%.

The present invention is not limited to the examples described above. Many alternative versions are possible without departing from the scope defined by the appended claims.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A deposition reactor, in particular for the purpose of depositing a film of oxide having a high permittivity or dielectric constant on a wafer, which comprises:
an enclosure defining a treatment chamber;
a support on which a wafer having an upper face to be treated can be placed in said treatment chamber;
a plate-shaped diffuser, which has through-holes between a front face placed above and at some distance from the upper face of the wafer to be treated and a rear face opposite this front face and which divides said treatment chamber into a distribution chamber located on the same side as the rear face of the diffuser and a reaction chamber located on the same side as the front face of the diffuser; and
an annular passage formed in the reaction chamber around said support,
said enclosure being provided with reaction gas intake means opening into said distribution chamber, peripheral gas exhaust means opening into said reaction chamber on the same side as the wafer relative to said annular passage, and dilution gas intake means opening into said reaction chamber and placed so that this gas flows through said annular passage before being exhausted via said gas exhaust means,
wherein the peripheral part of said front face of the diffuser is formed so that the gap between this peripheral part and the upper face of said wafer to be treated decreases from the periphery of the diffuser towards its center.

2. The reactor according to claim 1, wherein said peripheral part of the front face of the diffuser is conical.

3. The reactor according to claim 2, wherein the cone angle of said conical peripheral part of the front face of the diffuser ranges from 160° to 175°.

4. The reactor according to claim 1, wherein said peripheral part of the front face of the diffuser is rounded.

5. The reactor according to claim 1, wherein a central part of the front face of the diffuser is set back or hollowed.

6. The reactor according to claim 5, wherein said central part of the front face of the diffuser has a conical annular part open on the same side as said wafer.

7. The reactor according to claim 6, wherein the cone angle of said conical central part of the front face of the diffuser ranges from 175° to 179.5°.

8. A method of determining the shape of the front face of a plate-shaped gas diffuser of a deposition reactor, said front face to be placed facing the surface of a circular wafer to be treated, in which the operating conditions of the reactor are predetermined, comprising:
installing in the reactor a first, trial diffuser, the front face of which has a defined profile, preferably a flat front face;
carrying out a deposition operation on a surface of a trial wafer;
recording the topography of the treated surface of the trial wafer;
producing a second diffuser having a front face whose topography has at least one annular part substantially reverse of the recorder topography of the treated surface of the trial wafer; and
installing this second diffuser in the reactor for the purpose of treating standard wafers.

9. The method according to claim 8, wherein producing comprises producing a second diffuser whose front face has at least one conical or rounded annular part whose cone angle is substantially the reverse of and in a defined ratio with respect to a mean cone angle of the corresponding annular part of the trial wafer.

10. The method according to claim 9, wherein said conical or rounded annular part is located on the periphery of the front face of said second diffuser.

11. A plate-shaped diffuser for a deposition reactor, comprising a front face intended to be placed above and at some distance from an upper face of a wafer to be treated and a rear face opposite this front face and which has through-holes made between these faces, wherein a peripheral part of said front face is formed so that the gap between this peripheral part and the upper face of said wafer to be treated decreases from a periphery of the diffuser towards its center.

12. The diffuser according to claim 11, wherein said peripheral part of the front face of the diffuser is conical.

13. The diffuser according to claim 12, wherein the cone angle of said conical peripheral part of the front face of the diffuser ranges from 160° to 175°.

14. The diffuser according to claim 11, wherein said peripheral part of the front face of the diffuser is rounded.

15. The diffuser according to claim 11, wherein the central part of the front face of the diffuser is set back or hollowed.

16. The diffuser according to claim 15, wherein said central part of the front face of the diffuser has a conical annular part open on the same side as said wafer.

17. The diffuser according to claim 16, wherein the cone angle of said conical central part of the front face of the diffuser ranges from 175° to 179.5°.

18. A deposition reactor, in particular for the purpose of depositing a film of oxide having a high permittivity or dielectric constant on a wafer, comprising:
an enclosure defining a treatment chamber;
a support on which a wafer having an upper face to be treated can be placed in said treatment chamber;
a plate-shaped diffuser, which has through-holes between a front face placed above and at some distance from the upper face of the wafer to be treated and a rear face opposite this front face and which divides said treatment chamber into a distribution chamber located on the same side as the rear face of the diffuser and a reaction chamber located on the same side as the front face of the diffuser;
an annular passage formed in the reaction chamber around said support,
said enclosure being provided with reaction gas intake means opening into said distribution chamber, peripheral gas exhaust means opening into said reaction chamber on the same side as the wafer relative to said annular passage, and dilution gas intake means opening into said reaction chamber and placed so that this gas flows through said annular passage before being exhausted via said gas exhaust means,
said dilution gas intake means comprising flow control means.

19. A deposition reactor, in particular for the purpose of depositing a film of oxide having a high permittivity or dielectric constant on a wafer, comprising:
an enclosure defining a treatment chamber;
a support on which a wafer having an upper face to be treated can be placed in said treatment chamber;
a plate-shaped diffuser, which has through-holes between a front face placed above and at some distance from the upper face of the wafer to be treated and a rear face opposite this front face and which divides said treatment chamber into a distribution chamber located on the same side as the rear face of the diffuser and a reaction chamber located on the same side as the front face of the diffuser;
an annular passage formed in the reaction chamber around said support,
said enclosure being provided with reaction gas intake means opening into said distribution chamber, peripheral gas exhaust means opening into said reaction chamber on the same side as the wafer relative to said annular passage, and dilution gas intake means opening into said reaction chamber and placed so that this gas flows through said annular passage before being exhausted via said gas exhaust means,
at least two independent local heating/cooling means that are carried by the wall of the enclosure adjacent to said distribution chamber and located in the peripheral region of this chamber, and also independent means for controlling and/or regulating the thermal power provided by these heating/cooling means.

20. The reactor according to claim 19, wherein said local heating/cooling means are attached to the outer face of said wall of the enclosure.

21. The reactor according to claim 19, wherein said local heating/cooling means comprise electrical resistors.

22. The reactor according to claim 21, wherein said resistors are placed in a groove made in the outer face of said wall of the enclosure.

23. The reactor according to any claim 19, wherein said independent control and/or regulation means comprise thermal sensors carried by said wall of the enclosure and located in the vicinity of said independent local heating/cooling means, control means for setting temperature setpoint values, and regulating means for regulating said heating means so that said thermal sensors deliver measurements corresponding to said setpoint values.

24. A deposition reactor, comprising:
an enclosure defining a treatment chamber for a wafer having an upper face to be treated; and
a plate-shaped diffuser having through-holes between a front face placed above and at some distance from the upper face of the wafer to be treated and a rear face opposite this front face, wherein a peripheral part of said front face of the diffuser is formed so that a gap between the front face of the diffuser at this peripheral part and the upper face of said wafer to be treated decreases from the periphery of the diffuser towards its center.

25. The reactor according to claim 24, wherein said peripheral part of the front face of the diffuser is conical.

26. The reactor according to claim 2, wherein a cone angle of said conical peripheral part of the front face of the diffuser ranges from 160° to 175°.

27. The reactor according to claim 1, wherein said peripheral part of the front face of the diffuser is rounded.

28. The reactor according to claim 1, wherein a central part of the front face of the diffuser is set back or hollowed.

29. The reactor according to claim 5, wherein said central part of the front face of the diffuser has a conical annular part open on the same side as said wafer.

30. The reactor according to claim 6, wherein a cone angle of said conical central part of the front face of the diffuser ranges from 175° to 179.5°.
